(19) United States
(12) Patent Application Publication
(10) Pub. No.: US 2013/0220672 A1
(43) Pub. Date: Aug. 29, 2013

(54) Single Layer Touch-Control Sensor Structure With Reduced Coupling To Proximate Ground Structures

(71) Applicants: Mykola Golovchenko, Cupertino, CA (US); Stanislav Pereverzev, Cupertino, CA (US); William Stacy, San Jose, CA (US)

(72) Inventors: Mykola Golovchenko, Cupertino, CA (US); Stanislav Pereverzev, Cupertino, CA (US); William Stacy, San Jose, CA (US)

(73) Assignee: TOUCH TURNS, LLC, Santa Clara, CA (US)

(21) Appl. No.: 13/406,744

(22) Filed: Feb. 28, 2012

(51) Int. Cl. H05K 1/00; H05K 3/10; G03F 7/20

(52) U.S. Cl. 174/250; 430/322; 29/846

(57) ABSTRACT

The invention is a structure and method for creating areas of non-conducting or isolated conducting surfaces within an area of conducting surfaces such that the capacitance of said conducting surface is reduced relative to a proximate, essentially parallel, conducting surface.

This application incorporates US Patent and Trademark Office utility patent application number 13279139 as to drawings and descriptions related to the variety of reduced-bond structures. The structures described and claimed in this application are based on the structures described in application Ser. No. 13/279,139 with the addition of the novel structure aspects described, herein, which support higher touch-control performance.

### TECHNICAL FIELD

The present invention relates to a structure and method for connecting touch-panel sensor electrodes to related electronic control subsystems for use in devices featuring touch-screen control.

### BACKGROUND OF THE INVENTION

Many of today's electronic devices, portable devices in particular, feature touch-panel control where a user touches a particular area of a glass screen, or an icon displayed below such a screen, and a subsystem detects that touch and performs a related control function. Touch-panel equipped glass screens are an alternative, for example, to having push-button or keyboard type input devices. In addition to sensing the location of a finger touch, such touch-panel screen controls can also be used to sense motion of the finger touch from one point to another and can respond by, for example, moving the position of an image, drawing a line segment, or increasing or decreasing the magnification of an image. These touch-panels and their control functions are well known in the art.

There are a variety of technologies used in touch-panel equipped systems to determine the position, relative to the screen, of the finger touch. One of the more current and popular technologies uses a mutual-capacitance sensing approach. For mutual-capacitance sensing, using a variety of materials and methods, an array of sensor electrodes are placed, coplanar, onto a transparent glass screen consisting of so-called transmitter and receiver electrodes in close proximity to one another. The mutual capacitance between such electrodes arises from the fringing fields between such electrodes and is dependent on the length of the proximate (i.e. shared) edges. A voltage is applied to the transmitter electrode and the detector integrates the current at the receiver which is proportional to the mutual capacitance between the transmitter and receiver electrodes. The transmitter and receiver electrodes must remain isolated from one another, that is, the impedance measured between any two electrodes must be very high. The presence of a finger touch will add capacitance to ground lowering the effective mutual capacitance, and indicate where in the spatial array of transmitter and receiver electrodes the lowered mutual capacitance has occurred. That will coincide with where the finger has touched the glass panel. This is prior art and well known to someone practiced in the art.

The time it takes for a finger touch to be detected and processed is in part related to the charging behavior at the touched point. That, in turn, is related to the mutual capacitance of the touched electrode to the proximate electrode and to the parasitic capacitance to proximate ground structures. The parasitic capacitance, unlike the mutual capacitance between electrodes, involves the electrodes and nearby ground surfaces which are not coplanar. Here, the parasitic capacitance is dependent on the area of the electrodes and the proximate ground surfaces.

If that parasitic capacitance to proximate ground structures can be reduced, the charging time, a function of resistance and capacitance, is also reduced and detection performance is increased.

Therefore, a way of reducing that capacitance to proximate ground structures would be of benefit and interest to those practiced in the art.

### BRIEF SUMMARY OF THE INVENTION

It is, therefore, an object of the present invention to reduce the capacitance between sensor electrodes and proximate ground structures.

Capacitance between two essentially parallel conducting surfaces is directly proportional to the respective areas of the surfaces and inversely proportional to the distance that separates them.

Therefore, one way to reduce the capacitance between a sensor electrode and proximate ground structure would be to increase the distance between them.

Another way would be to reduce the surface area of the electrode and/or proximate ground structure.

In the exemplary descriptions of the electrode structures included herein, the surface areas of the electrodes are reduced without affecting the mutual capacitance between those electrodes and proximate sensor electrodes.

This results in reduced parasitic capacitance and thus decreases the time lag which charging that parasitic capacitance has on sensor speed. As a result, sensor speed performance increases.

### BRIEF DESCRIPTIONS OF THE DRAWINGS

FIG. 1 depicts a typical, prior art, touch sensor circuit. A driving voltage on the one sensor electrode causes charge to pass through the electrode resistance (102) and the mutual capacitance between it and the other sensor electrode (103). The second sensor electrodes resistivity (104) will have retarding effect on the sensor signal at 105. The capacitances, 106 and 107, represent the parasitic capacitance between the electrodes and the proximate ground structure.

FIG. 2 shows the approximate relationship between capacitance, area and distance between two conducting surfaces, neglecting edge fringing effects. As shown, the capacitance is proportional to the area of one side of each surface (Al, for example). Assuming the areas are the same, the proportionality depends on either A1 or A2.

FIG. 3 shows the case where the upper surface's area A is diminished by removing an area, a, of conductive material. The remaining area of that surface is now A-a; and the capacitance is now proportional to A-a. Consequently, the capacitance has been reduced.

FIG. 4 is similar to FIG. 3 but the conducting area, a, is not removed. Rather, a non-conducting border is created around area, a, such that it is electrically isolated from the rest of area A. This would have the same effect as removing the entire area, a, and would make the capacitance approximately proportional to A-a.

FIG. 5 depicts a sensor pattern as shown in, described, and incorporated from application Ser. No. 13/279,139. The shapes of these sensor electrodes provide optimized mutual capacitance between the proximate sensor electrodes.

FIG. 6 depicts the same sensor pattern as shown in FIG. 5 where areas of the electrodes, presented by the white squares, have been removed creating non-conducting islands. These islands do not reduce the mutual capacitance between the proximate sensor electrodes because those are determined primarily by the length of the adjacent sides. However, the islands do reduce the area of these electrodes and, as such, reduce the capacitance of those electrodes with a proximate ground surface. Note that the islands can be created by removing all the conducting material within the area denoted by the white squares, or by creating a non-conducting border around the conducting area as in FIG. 4.

FIG. 7 shows a sensor electrode pattern described in and incorporated from application Ser. No. 13/279,139. Here, again, the pattern is arranged in such a fashion as to optimize the mutual capacitance between the proximate sensor electrodes. Here, again, the islands, shown as white squares, represent areas of conducting surface that have been removed from the electrodes, or an isolated conducting surface with a border of conducting material removed. Note, again, that the islands can be created by removing all the conducting material within the area denoted by the white squares, or by creating a non-conducting border around the conducting area as in FIG. 4. The reduced surface area will reduce the parasitic capacitance between these sensor electrodes and a proximate ground surface. They will not materially affect the mutual capacitance between the proximate sensor electrodes.

### DETAILED DESCRIPTION OF THE INVENTION

The following description covers the structure and methods used for reducing the capacitance between single-layer sensor electrodes and a proximate ground surface. The drawings and descriptions are exemplary and should not be interpreted as limiting the scope of the invention to those particular electrode patterns and island shapes.

A typical single-layer touch sensor panel consists of transmitter and receiver electrodes that are coplanar and proximate to one another but which are to all intents isolated electrically from one another except for the mutual capacitance they share as a consequence of their proximate edges.

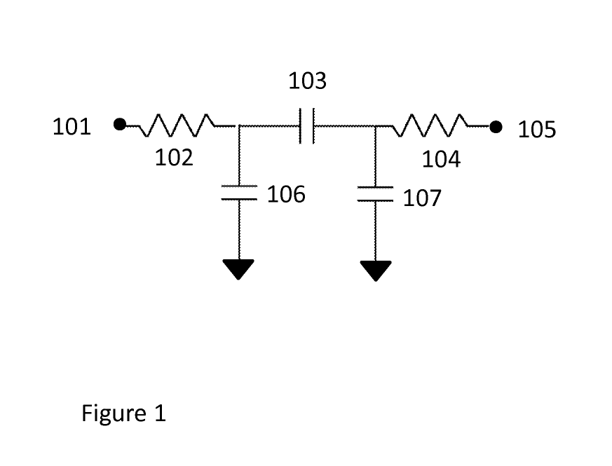

As shown in FIG. 1, an electrode 101 has resistivity (102), parasitic capacitance to a ground surface (106), and mutual capacitance (103) to a second electrode (105) which also has resistivity (104) and parasitic capacitance (107). A voltage is applied to 101 and the resulting current induced on a receiver electrode is measured at 105 The many transmitter and receiver electrodes are arranged in a dense array on the single surface of the sensor panel glass. The amount of induced current is directly related to the mutual capacitance between the driver electrode and receiver electrode. This measurement is done very quickly for each combination of driver and receiver pairs in the array and, in this way, a matrix of capacitance values is generated. When a human finger is brought close to the sensor electrode array, the local capacitance values are perturbed. Some charge is removed via the capacitive coupling of the human body to earth ground. As a result, the local perturbation of the capacitance array can be correlated with the touch location and the spatial coordinates of the finger touch can be reported. Since each mutual capacitance point is measured independently, any number of touches (fingers) can be tracked simultaneously. This is the basic operation of a multi-finger tracking system using mutual capacitance.

In general, the greater the mutual capacitance between the transmitter and receiver electrodes, the greater the perturbation in capacitance caused by the touch and the more readily detectable it becomes. Thus, one design objective is to increase the mutual capacitance between the electrodes. This is described and claimed in application Ser. No. 13/279,139 which is incorporated hereby.

The parasitic capacitance between the transmitter and receiver electrodes, and a proximate ground surface, adds some charging lag time to touch detection which is proportionate to the amount of parasitic capacitance. Thus, if the parasitic capacitance can be reduced, so can this lag time. That, in turn, will improve touch detection performance.

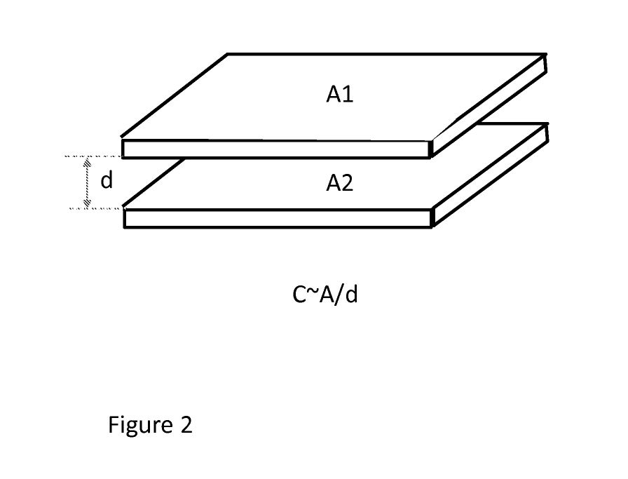

Referring to FIG. 2, the capacitance between two conducting surfaces, 1 and 2, is proportional to the area of sides closest to one another and the distance between those surfaces. Hence, in this case, we find that C˜A/d.

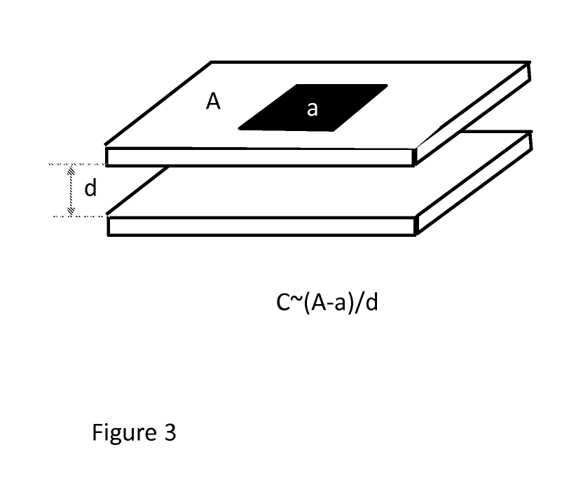

Referring to FIG. 3, where one of the surfaces from FIG. 2 (surface 1) has had its area reduced by a, we now have a reduced capacitance, C˜(A-a)/d. Thus, if the area of one of two proximate surfaces can be reduced, the capacitance between them will also be reduced.

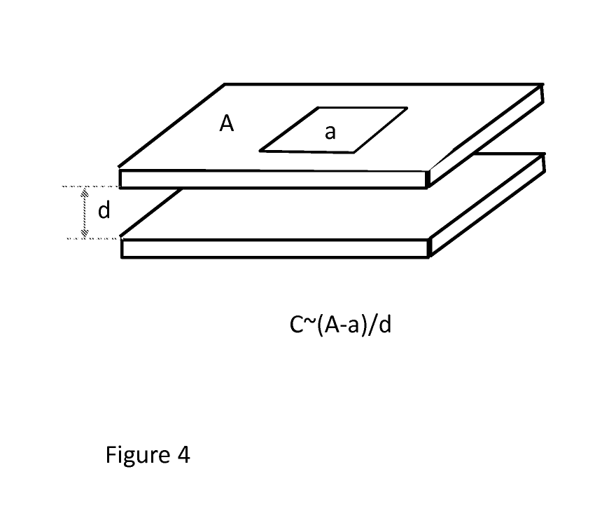

Referring to FIG. 4, where one of the surfaces from FIG. 2 (surface 1) has had its area reduced by a by removing conducting material from the border surrounding a, we now have a reduced capacitance, C˜(A-a)/d.

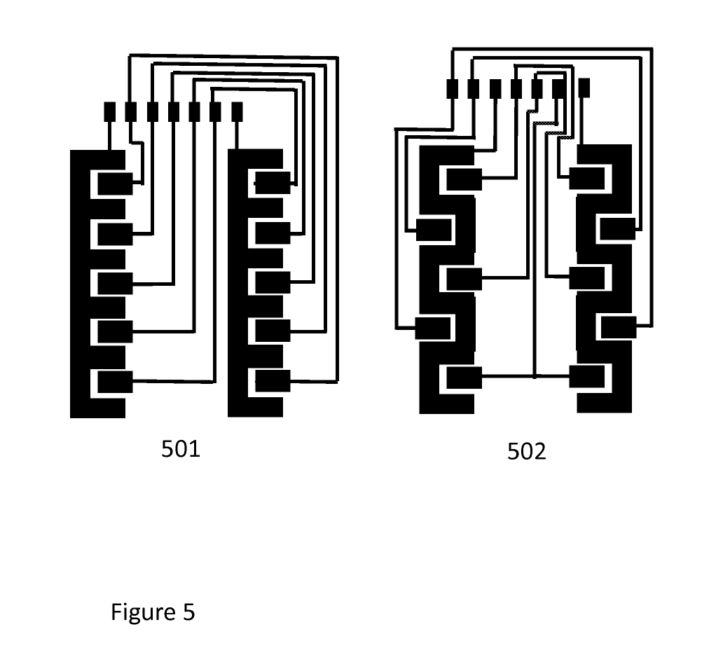

Referring to FIG. 5, these two electrode patterns (501 and 502) represent electrode structure patterns that increase mutual capacitance between the electrodes and therefore increase touch detection sensitivity. In essence the shape of the inter-fingering structures increases the lengths of the proximate sides which increase the mutual capacitance.

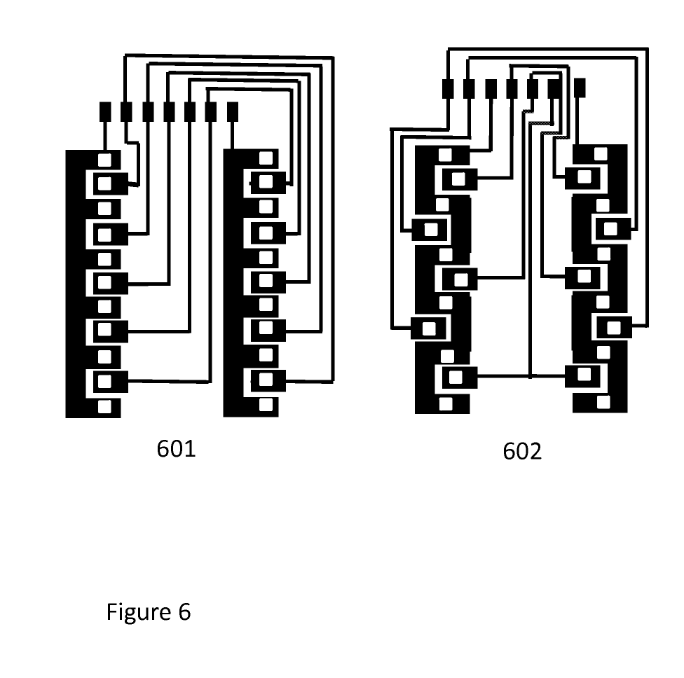

Referring to FIG. 6, the same electrode pattern as was depicted in FIG. 5 is now shown where areas of the conducting surfaces have been reduced by removing an area of conducting material, or by removing the conducting material from the border around said area, leaving an island of non-conducting or isolated conducting area (as shown by the white squares). Because these islands do not reduce the linear dimensions of the proximate sides of the sensor electrodes, they have essentially no effect on the mutual capacitance between them. However, because these islands do reduce the conducting areas of the electrodes, they will reduce the parasitic capacitance between those electrodes and a proximate ground surface.

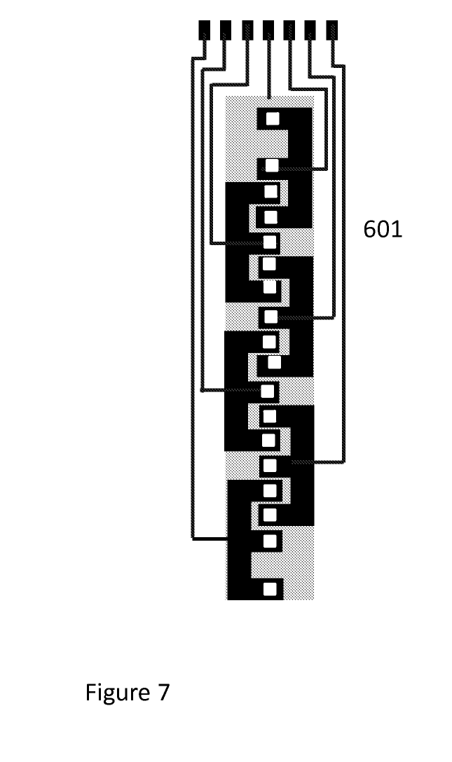

Referring to FIG. 7, this pattern is also based on a pattern described in application Ser. No. 13/279,139 and incorporated hereby. Here, again, the white squares represent areas of the conducting surfaces of these electrodes that have been removed or where conducting material has been removed from the border around said area thereby isolating them electrically from the rest of the surface. The primary results of so doing is to reduce the coupling capacitance between these electrodes and proximate ground surfaces.

The structures which provide the reduced capacitance to the proximate ground surfaces are the same as those which increase the mutual capacitance between the sensor electrodes. The reduced capacitance is a result of reducing the area of the conductive surfaces of these sensor electrodes. Touch-control sensors are typically manufactured by laying down a uniform, thin, layer of transparent conducting surface materials and then laser scribing out the particular pattern of transmitter and receiver electrodes and bonds. In such cases, the islands can be created by scribing out the border around the area to be removed, as shown in FIG. 4. Alternatively, that border can be created using photolithography with wet or dry etching. Similarly, islands made by removing all conductive material from its area can be implemented using laser scribing or photolithography plus wet or dry etching. In either case, the area is no longer part of the original conducting surface and will reduce the capacitance to proximate ground surfaces.

1. A structure for reducing capacitive coupling between transparent conducting electrode sensor electrodes and proximate ground surfaces comprising:
One or a plurality of transparent conductive electrodes;
One or a plurality of non-conducting islands in the surface or surfaces of said transparent conductive electrodes.

2. A structure for reducing capacitive coupling between said transparent conducting electrode sensor electrodes and proximate ground surfaces comprising:
One or a plurality of said transparent conductive electrodes;
One or a plurality of isolated conducting islands in the surface or surfaces of said transparent conducting electrodes.

3. A method for creating said non-conducting islands comprising:
Depositing a layer of transparent conducting electrode material on one surface of a sensor glass;
Using photolithographic masking and wet etching to remove some portion of said transparent conducting electrode material to from said non-conducting island within a larger area of said conducting electrode material.

4. A method for creating said non-conducting islands comprising:
Depositing a layer of said transparent conducting electrode material on one surface of a sensor glass;
Using photolithographic masking and dry etching to remove some portion of said transparent conducting electrode material to form said non-conducting island with a larger area of said transparent conducting electrode material.

5. A method for creating said non-conducting islands comprising:
Depositing a layer of said transparent conducting electrode material on one surface of a sensor glass;
Using laser ablation to remove some portion of said transparent conducting electrode material to form a non-conducting island within a larger area of said transparent conducting electrode material.

6. A method for creating said isolated conducting islands comprising:
Depositing a layer of said transparent electrode material on one surface of a sensor glass;
Using photolithography and wet etching to remove a continuous closed border of said transparent electrode material to create said isolated conducting island.

7. A method for creating said isolated conducting islands comprising:
Depositing a layer of said transparent electrode material on one surface of a sensor glass;
Using photolithography and dry etching to remove a continuous closed border of said transparent electrode material to create said isolated conducting island.

8. A method for creating said isolated conducting islands comprising:
Depositing a layer of said transparent electrode material on one surface of a sensor glass;
Using direct removal by laser ablation of a continuous closed border of said transparent electrode material to create said isolated conducting island.
